(19) United States
(12) Patent Application Publication
(10) Pub. No.: US 2024/0429143 A1
(43) Pub. Date: Dec. 26, 2024

(54) POWER MODULE STRUCTURE

(71) Applicant: Delta Electronics, Inc., Taoyuan City (TW)

(72) Inventors: Jung-Li CHEN, Taoyuan City (TW); Yu-Hsuan TSAI, Taoyuan City (TW); Chang-Chin TSAI, Taoyuan City (TW)

(21) Appl. No.: 18/643,589

(22) Filed: Apr. 23, 2024

Related U.S. Application Data
(60) Provisional application No. 63/509,425, filed on Jun. 21, 2023.

(30) Foreign Application Priority Data
Dec. 27, 2023 (TW) 112150973

(51) Int. Cl. H01L 23/498; H01L 23/00; H01L 23/31; H01L 23/373

(52) U.S. Cl. CPC H01L 23/49811; H01L 23/3121; H01L 23/3735; H01L 23/49866; H01L 24/32; H01L 24/48; H01L 24/49; H01L 24/73; H01L 2224/32225; H01L 2224/48091; H01L 2224/48225; H01L 2224/49175; H01L 2224/73265

(57) ABSTRACT

A power module structure is provided. The power module structure includes a substrate, a chip, a first metal structure, a second metal structure and a packaging material. The chip, the first metal structure and the second metal structure are disposed on the substrate. From a cross-sectional view, the width of the first metal structure is greater than the width of the second metal structure. The packaging material covers the substrate and the chip, and the portions of the first metal structure and the second metal structure are exposed from the upper surface of the packaging material.

### CROSS REFERENCE TO RELATED APPLICATIONS

This application claims priority of U.S. Provisional Application Ser. No. 63/509,425, filed on Jun. 21, 2023, and priority of Taiwan Patent Application No. 112150973, filed on Dec. 27, 2023, the entirety of which are incorporated by reference herein.

### BACKGROUND OF THE INVENTION

### Field of the Invention

The present disclosure relates to a power module structure, and, in particular, to a power module structure with a vertical signal conduction path.

### Description of the Related Art

At present, in a power module, a nail frame connected to a base substrate is often used as a signal conduction path. After glue is filled in and the module is sealed, the pins of the nail frame extend outwards to conduct current and signals as a connection to a system.

However, the nail frame increases the overall size of the power module, and the circuit design is more complicated. The orientation and size of pins of the nail frame need to be considered.

### BRIEF SUMMARY OF THE INVENTION

In accordance with one embodiment of the present disclosure, a power module structure is provided. The power module structure includes a substrate, a chip, a first metal structure, a second metal structure and a packaging material. The chip, the first metal structure and the second metal structure are disposed on the substrate. From a cross-sectional view, the width of the first metal structure is greater than the width of the second metal structure. The packaging material covers the substrate and the chip, and the portions of the first metal structure and the second metal structure are exposed from the upper surface of the packaging material.

In some embodiments, the substrate includes aluminum oxide. In some embodiments, the chip includes a power component. In some embodiments, the first metal structure and the second metal structure include copper, silver or aluminum.

In some embodiments, the upper surfaces of the first metal structure and the second metal structure are on the same plane as the upper surface of the packaging material. In some embodiments, the upper surfaces of the first metal structure and the second metal structure are higher than the upper surface of the packaging material. In some embodiments, the upper surfaces of the first metal structure and the second metal structure are lower than the upper surface of the packaging material.

In some embodiments, the power module structure further includes another first metal structure disposed on the substrate. A portion of the other first metal structure is exposed from the upper surface of the packaging material. In some embodiments, from a top view, the first metal structure and the other first metal structure have different areas. In some embodiments, from a top view, the first metal structure and the other first metal structure have different shapes. In some embodiments, from a top view, the first metal structure and the other first metal structure include a rectangle, a triangle or a circle in shape.

In some embodiments, from a cross-sectional view, the first metal structure includes a rectangle or an irregular shape. In some embodiments, the first metal structure further includes a through hole.

In the power module structure of the present disclosure, the first metal structure and the second metal structure for signal conduction are disposed on the substrate and exposed from the upper surface of the packaging material to conduct signals from the substrate to the surface of the packaging material. Then, the first metal structure and the second metal structure are connected to a power pin and a signal pin respectively through the post-processes. In the present disclosure, the circuit can be shortened to a minimum by conducting signals vertically to achieve rapid conduction of current and signals. Since the first metal structure is a solid structure, large current transmission can be achieved. In addition, the relative positional relationship between the first metal structure, the second metal structure and the packaging material in the disclosed power module structure can be appropriately adjusted according to product requirements, and the manufacturing process is simple. Furthermore, the dimension, quantity, position, shape, three-dimensional structure, etc. of the plurality of first metal structures in the disclosed power module structure can also be adjusted appropriately according to product requirements, and the manufacturing process is simple. For example, designing the first metal structure into an I-shape can increase the bonding area and bonding force between the first metal structure and the packaging material. For another example, designing the first metal structure to include a through-hole structure can increase the bonding force between the first metal structure and the packaging material.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a cross-sectional view of a power module structure in accordance with one embodiment of the present disclosure;

FIG. 2A shows a cross-sectional view of a power module structure in accordance with one embodiment of the present disclosure;

FIG. 2B shows a cross-sectional view of a power module structure in accordance with one embodiment of the present disclosure;

FIG. 2C shows a cross-sectional view of a power module structure in accordance with one embodiment of the present disclosure;

FIG. 3 shows a top view of a power module structure in accordance with one embodiment of the present disclosure;

FIG. 4 shows a top view of a power module structure in accordance with one embodiment of the present disclosure;

FIG. 5 shows a top view of a power module structure in accordance with one embodiment of the present disclosure;

FIG. 6 shows a top view of a power module structure in accordance with one embodiment of the present disclosure;

FIG. 7 shows a cross-sectional view of a power module structure in accordance with one embodiment of the present disclosure; and

FIG. 8 shows a cross-sectional view of a power module structure in accordance with one embodiment of the present disclosure.

### DETAILED DESCRIPTION OF THE INVENTION

Various embodiments or examples are provided in the following description to implement different features of the present disclosure. The elements and arrangement described in the following specific examples are merely provided for introducing the present disclosure and serve as examples without limiting the scope of the present disclosure. For example, when a first component is referred to as “on a second component”, it may directly contact the second component, or there may be other components in between, and the first component and the second component do not come in direct contact with one another.

It should be understood that additional operations may be provided before, during, and/or after the described method. In accordance with some embodiments, some of the stages (or steps) described below may be replaced or omitted.

In this specification, spatial terms may be used, such as “below”, “lower”, “above”, “higher” and similar terms, for briefly describing the relationship between an element relative to another element in the figures. Besides the directions illustrated in the figures, the components may be used or operated in different directions. When the component is turned to different directions (such as rotated 45 degrees or other directions), the spatially related adjectives used in it will also be interpreted according to the turned position. In some embodiments of the present disclosure, terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Herein, the terms “about”, “around” and “substantially” typically mean a value is in a range of +/−15% of a stated value, typically a range of +/−10% of the stated value, typically a range of +/−5% of the stated value, typically a range of +/−3% of the stated value, typically a range of +/−2% of the stated value, typically a range of +/−1% of the stated value, or typically a range of +/−0.5% of the stated value. The stated value of the present disclosure is an approximate value. Namely, the meaning of “about”, “around” and “substantially” may be implied if there is no specific description of “about”, “around” and “substantially”.

It should be understood that, although the terms “first”, “second”, “third”, etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer, portion or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

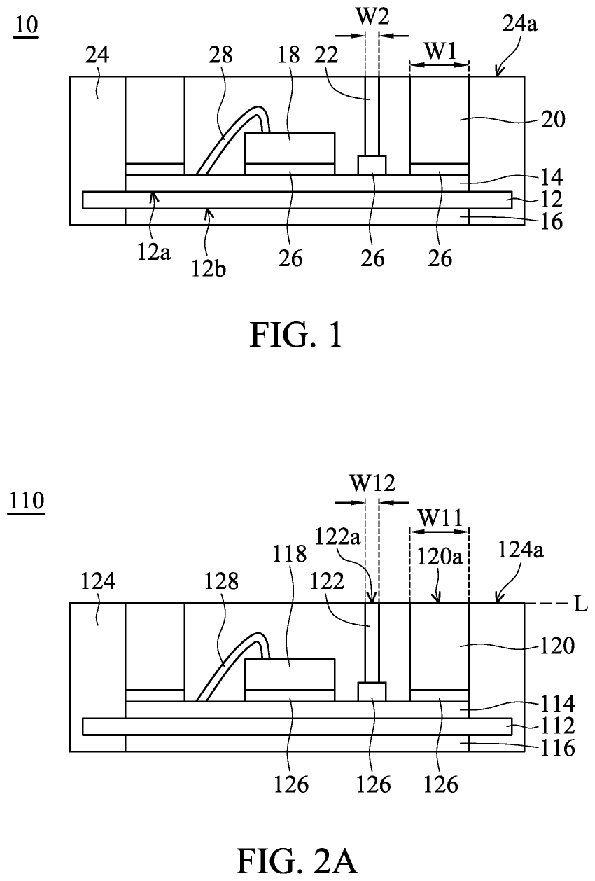

Referring to FIG. 1, in accordance with one embodiment of the present disclosure, a power module structure 10 is provided. FIG. 1 shows a cross-sectional view of the power module structure 10.

As shown in FIG. 1, the power module structure 10 includes a substrate 12, a first copper layer 14, a second copper layer 16, a chip 18, a first metal structure 20, a second metal structure 22 and a packaging material 24. The first copper layer 14 is disposed on the first surface 12a of the substrate 12. The second copper layer 16 is disposed on the second surface 12b of the substrate 12. The second surface 12b is opposite to the first surface 12a. The chip 18 is disposed on first copper layer 14 (i.e. on the substrate 12) through the solder 26. The first metal structure 20 is disposed on the first copper layer 14 (i.e. on the substrate 12) through the solder 26. The second metal structure 22 is disposed on the first copper layer 14 (i.e. on the substrate 12) through the solder 26. In addition, the chip 18 is connected to the first copper layer 14 (i.e. connected to the substrate 12) through a metal wire 28. The packaging material 24 covers the substrate 12 and the chip 18. It is worth noting that the width W1 of the first metal structure 20 is greater than the width W2 of the second metal structure 22, and the portions of the first metal structure 20 and the second metal structure 22 are exposed from the upper surface 24a of the packaging material 24.

In some embodiments, the material of the substrate 12 includes aluminum oxide, but the present disclosure is not limited thereto, and other suitable substrate materials are also applicable to the present disclosure. In some embodiments, when the material of the substrate 12 is aluminum oxide (i.e. ceramic material), the composite plate composed of the substrate 12, the first copper layer 14, and the second copper layer 16 is called a ceramic substrate, as a carrier for the chip 18. The ceramic substrate has high thermal conductivity and electrical insulation properties.

In some embodiments, the chip 18 includes power components, such as high-power components.

In some embodiments, the material of the first metal structure 20 and the second metal structure 22 includes metal materials with high thermal conductivity and electrical conductivity, such as copper, silver, or aluminum, but the present disclosure is not limited thereto, and other suitable metal materials are also applicable to the present disclosure. In some embodiments, the first metal structure 20 is further connected to an external power pin. In some embodiments, the second metal structure 22 is further connected to an external signal pin. In some embodiments, the first metal structure 20 and the second metal structure 22 are disposed vertically on the first copper layer 14 (i.e. on the substrate 12). That is, the first metal structure 20 and the second metal structure 22 are designed as vertical signal conduction paths. The vertical signal conduction path will become the shortest signal conduction path in the module structure, which can achieve rapid conduction of current and signals.

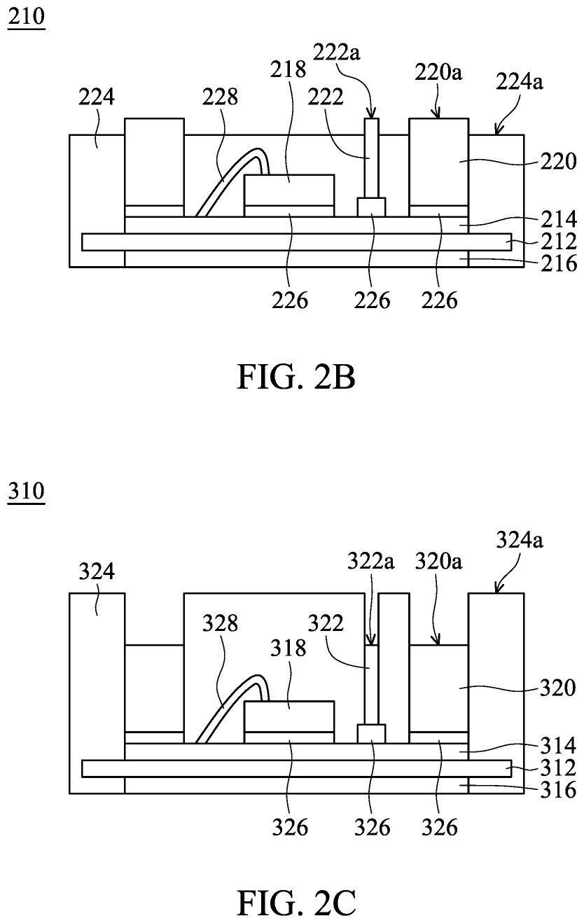

The relative positional relationship between the first metal structure, the second metal structure, and the packaging material in the power module structure will be further illustrated below with reference to the drawings (FIGS. 2A-2C).

Referring to FIG. 2A, in accordance with one embodiment of the present disclosure, a power module structure 110 is provided. FIG. 2A shows a cross-sectional view of the power module structure 110, mainly illustrating the relative positional relationship between the first metal structure, the second metal structure, and the packaging material in the power module structure 110.

As shown in FIG. 2A, the power module structure 110 includes a substrate 112, a first copper layer 114, a second copper layer 116, a chip 118, a first metal structure 120, a second metal structure 122 and a packaging material 124. The first copper layer 114 and the second copper layer 116 are disposed on two opposite surfaces of the substrate 112. The chip 118 is disposed on first copper layer 114 (i.e. on the substrate 112) through the solder 126. The first metal structure 120 is disposed on the first copper layer 114 (i.e. on the substrate 112) through the solder 126. The second metal structure 122 is disposed on the first copper layer 114 (i.e. on the substrate 112) through the solder 126. In addition, the chip 118 is connected to the first copper layer 114 (i.e. connected to the substrate 112) through a metal wire 128. The packaging material 124 covers the substrate 112 and the chip 118. Furthermore, the width W11 of the first metal structure 120 is greater than the width W12 of the second metal structure 122, and the portions of the first metal structure 120 and the second metal structure 122 are exposed from the upper surface 124a of the packaging material 124.

In some embodiments, the material of the substrate 112 includes aluminum oxide, but the present disclosure is not limited thereto, and other suitable substrate materials are also applicable to the present disclosure. In some embodiments, when the material of the substrate 112 is aluminum oxide (i.e. ceramic material), the composite plate composed of the substrate 112, the first copper layer 114, and the second copper layer 116 is called a ceramic substrate, as a carrier for the chip 118. The ceramic substrate has high thermal conductivity and electrical insulation properties.

In some embodiments, the chip 118 includes power components, such as high-power components.

In some embodiments, the material of the first metal structure 120 and the second metal structure 122 includes metal materials with high thermal conductivity and electrical conductivity, such as copper, silver, or aluminum, but the present disclosure is not limited thereto, and other suitable metal materials are also applicable to the present disclosure. In some embodiments, the first metal structure 120 is further connected to an external power pin. In some embodiments, the second metal structure 122 is further connected to an external signal pin. In some embodiments, the first metal structure 120 and the second metal structure 122 are disposed vertically on the first copper layer 114 (i.e. on the substrate 112). That is, the first metal structure 120 and the second metal structure 122 are designed as vertical signal conduction paths. The vertical signal conduction path will become the shortest signal conduction path in the module structure, which can achieve rapid conduction of current and signals.

It is worth noting that in FIG. 2A, the upper surface 120a of the first metal structure 120, the upper surface 122a of the second metal structure 122 and the upper surface 124a of the packaging material 124 are on the same plane L.

Referring to FIG. 2B, in accordance with one embodiment of the present disclosure, a power module structure 210 is provided. FIG. 2B shows a cross-sectional view of the power module structure 210, mainly illustrating the relative positional relationship between the first metal structure, the second metal structure, and the packaging material in the power module structure 210.

As shown in FIG. 2B, the power module structure 210 includes a substrate 212, a first copper layer 214, a second copper layer 216, a chip 218, a first metal structure 220, a second metal structure 222, a packaging material 224, solder 226, and a metal wire 228. The configuration and material of each component, the dimensional relationship between the components, and the bonding manner between the components in the power module structure 210 shown in FIG. 2B are similar to those of the power module structure 110 shown in FIG. 2A, and will not be described again here. The main difference between the embodiment shown in FIG. 2B and the embodiment shown in FIG. 2A lies in the relative positional relationship between the first metal structure, the second metal structure, and the packaging material in the power module structure. In FIG. 2B, the upper surface 220a of the first metal structure 220 and the upper surface 222a of the second metal structure 222 are higher than the upper surface 224a of the packaging material 224.

Referring to FIG. 2C, in accordance with one embodiment of the present disclosure, a power module structure 310 is provided. FIG. 2C shows a cross-sectional view of the power module structure 310, mainly illustrating the relative positional relationship between the first metal structure, the second metal structure, and the packaging material in the power module structure 310.

As shown in FIG. 2C, the power module structure 310 includes a substrate 312, a first copper layer 314, a second copper layer 316, a chip 318, a first metal structure 320, a second metal structure 322, a packaging material 324, solder 326, and a metal wire 328. The configuration and material of each component, the dimensional relationship between the components, and the bonding manner between the components in the power module structure 310 shown in FIG. 2C are similar to those of the power module structure 110 shown in FIG. 2A, and will not be described again here. The main difference between the embodiment shown in FIG. 2C and the embodiment shown in FIG. 2A lies in the relative positional relationship between the first metal structure, the second metal structure, and the packaging material in the power module structure. In FIG. 2C, the upper surface 320a of the first metal structure 320 and the upper surface 322a of the second metal structure 322 are lower than the upper surface 324a of the packaging material 324.

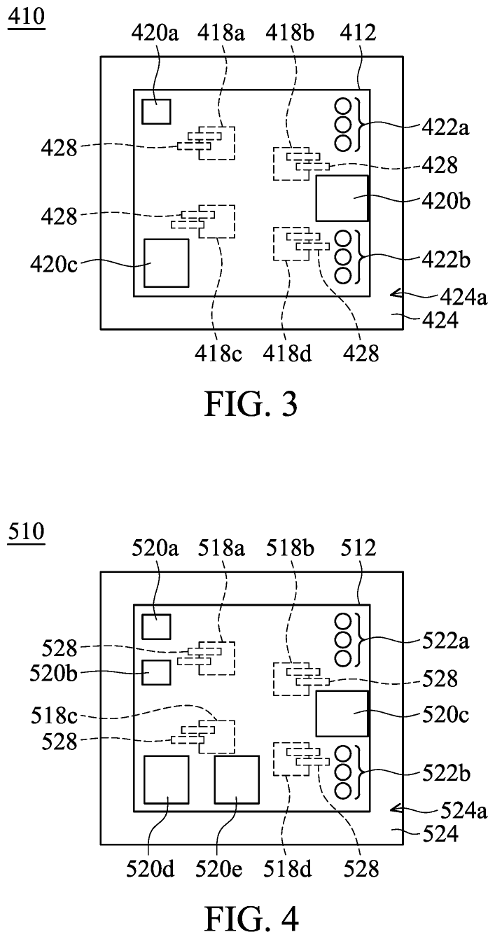

The alterations in dimension, quantity, position, and shape of the plurality of first metal structures in the power module structure will be further illustrated below with reference to the drawings (FIGS. 3-6).

Referring to FIG. 3, in accordance with one embodiment of the present disclosure, a power module structure 410 is provided. FIG. 3 shows a top view of the power module structure 410, mainly illustrating the alterations in dimension of the first metal structures in the power module structure 410.

As shown in FIG. 3, the power module structure 410 includes a substrate 412, a plurality of chips (418a, 418b, 418c and 418d), a plurality of first metal structures (420a, 420b and 420c), a plurality of second metal structures (422a and 422b), a packaging material 424, and metal wires 428. The chips (418a, 418b, 418c and 418d) are disposed on the substrate 412. The first metal structures (420a, 420b and 420c) are disposed on the substrate 412. The second metal structures (422a and 422b) are disposed on the substrate 412. In addition, the chips (418a, 418b, 418c and 418d) are connected to the substrate 412 through the metal wires 428. The packaging material 424 covers the substrate 412 and the chips (418a, 418b, 418c and 418d). The portions of the first metal structures (420a, 420b and 420c) and the second metal structures (422a and 422b) are exposed from the upper surface 424a of the packaging material 424.

In some embodiments, the material of the substrate 412 includes aluminum oxide, but the present disclosure is not limited thereto, and other suitable substrate materials are also applicable to the present disclosure. In some embodiments, when the material of the substrate 412 is aluminum oxide (i.e. ceramic material), the composite plate composed of the substrate 412 and the upper and lower copper layers disposed on the opposite surfaces of the substrate 412 is called a ceramic substrate, as a carrier for the chips (418a, 418b, 418c and 418d). The ceramic substrate has high thermal conductivity and electrical insulation properties.

In some embodiments, the chips (418a, 418b, 418c and 418d) include power components, such as high-power components.

In some embodiments, the material of the first metal structures (420a, 420b and 420c) and the second metal structures (422a and 422b) includes metal materials with high thermal conductivity and electrical conductivity, such as copper, silver, or aluminum, but the present disclosure is not limited thereto, and other suitable metal materials are also applicable to the present disclosure. In some embodiments, the first metal structures (420a, 420b and 420c) are further connected to an external power pin. In some embodiments, the second metal structures (422a and 422b) are further connected to an external signal pin. In some embodiments, the first metal structures (420a, 420b and 420c) and the second metal structures (422a and 422b) are disposed vertically on the substrate 412. That is, the first metal structures (420a, 420b and 420c) and the second metal structures (422a and 422b) are designed as vertical signal conduction paths. The vertical signal conduction path will become the shortest signal conduction path in the module structure, which can achieve rapid conduction of current and signals.

It is worth noting that, in the power module structure 410, according to product requirements, the first metal structures (420a, 420b and 420c) disposed on the substrate 412 can be designed to have different areas, as shown in FIG. 3.

Referring to FIG. 4, in accordance with one embodiment of the present disclosure, a power module structure 510 is provided. FIG. 4 shows a top view of the power module structure 510, mainly illustrating the alterations in quantity of the first metal structures in the power module structure 510.

As shown in FIG. 4, the power module structure 510 includes a substrate 512, a plurality of chips (518a, 518b, 518c and 518d), a plurality of first metal structures (520a, 520b, 520c, 520d and 520e), a plurality of second metal structures (522a and 522b), a packaging material 524, and metal wires 528. The configuration and material of some components in the power module structure 510 shown in FIG. 4 are similar to those of the power module structure 410 shown in FIG. 3, and will not be described again here. The main difference between the embodiment shown in FIG. 4 and the embodiment shown in FIG. 3 is that the number of the first metal structures in the power module structure is different. For example, in FIG. 3, the power module structure 410 includes three first metal structures (420a, 420b and 420c), and in FIG. 4, the power module structure 510 includes five first metal structures (520a, 520b, 520c, 520d and 520e), but the present disclosure is not limited thereto, and other suitable quantities of the first metal structure are also applicable to the present disclosure.

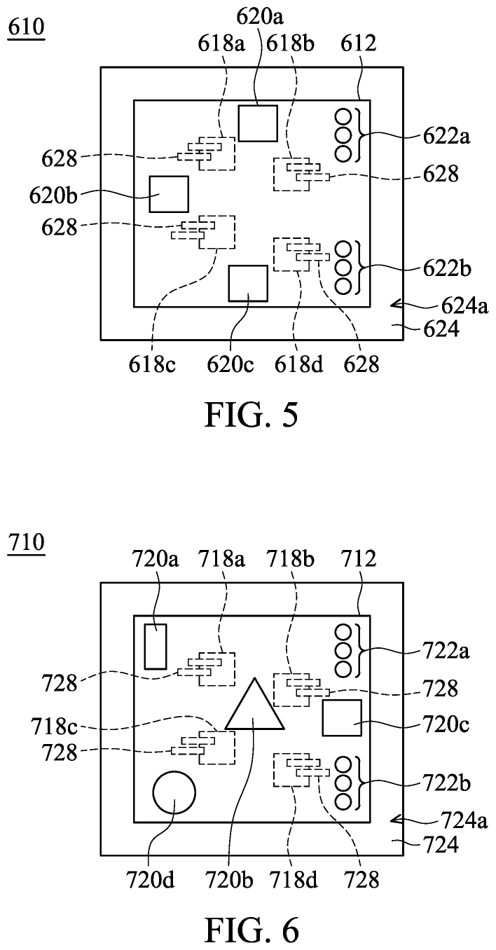

Referring to FIG. 5, in accordance with one embodiment of the present disclosure, a power module structure 610 is provided. FIG. 5 shows a top view of the power module structure 610, mainly illustrating the alterations in position of the first metal structures in the power module structure 610.

As shown in FIG. 5, the power module structure 610 includes a substrate 612, a plurality of chips (618a, 618b, 618c and 618d), a plurality of first metal structures (620a, 620b and 620c), a plurality of second metal structures (622a and 622b), a packaging material 624, and metal wires 628. The configuration and material of some components in the power module structure 610 shown in FIG. 5 are similar to those of the power module structure 410 shown in FIG. 3, and will not be described again here. The main difference between the embodiment shown in FIG. 5 and the embodiment shown in FIG. 3 is that the positions of the first metal structures in the power module structure are different. For example, in FIG. 3, the first metal structure 420a is adjacent to the chip 418a, the first metal structure 420b is disposed between the chip 418b and the chip 418d, and the first metal structure 420c is adjacent to the chip 418c. In FIG. 5, the first metal structure 620a is disposed between the chip 618a and the chip 618b, the first metal structure 620b is disposed between the chip 618a and the chip 618c, and the first metal structure 620c is disposed between the chip 618c and the chip 618d, but the present disclosure is not limited thereto, and other suitable positions of the first metal structures are also applicable to the present disclosure.

Referring to FIG. 6, in accordance with one embodiment of the present disclosure, a power module structure 710 is provided. FIG. 6 shows a top view of the power module structure 710, mainly illustrating the alterations in shape of the first metal structures in the power module structure 710.

As shown in FIG. 6, the power module structure 710 includes a substrate 712, a plurality of chips (718a, 718b, 718c and 718d), a plurality of first metal structures (720a, 720b, 720c and 720d), a plurality of second metal structures (722a and 722b), a packaging material 724, and metal wires 728. The configuration and material of some components in the power module structure 710 shown in FIG. 6 are similar to those of the power module structure 410 shown in FIG. 3, and will not be described again here. The main difference between the embodiment shown in FIG. 6 and the embodiment shown in FIG. 3 is that the shapes of the first metal structures in the power module structure are different. For example, in FIG. 3, the first metal structures (420a, 420b and 420c) are rectangular. In FIG. 6, the first metal structure 720a is a rectangle, the first metal structure 720b is a triangle, the first metal structure 720c is a rectangle, and the first metal structure 720d is a circle, but the present disclosure is not limited thereto, other suitable shapes of the first metal structures are also applicable to the present disclosure.

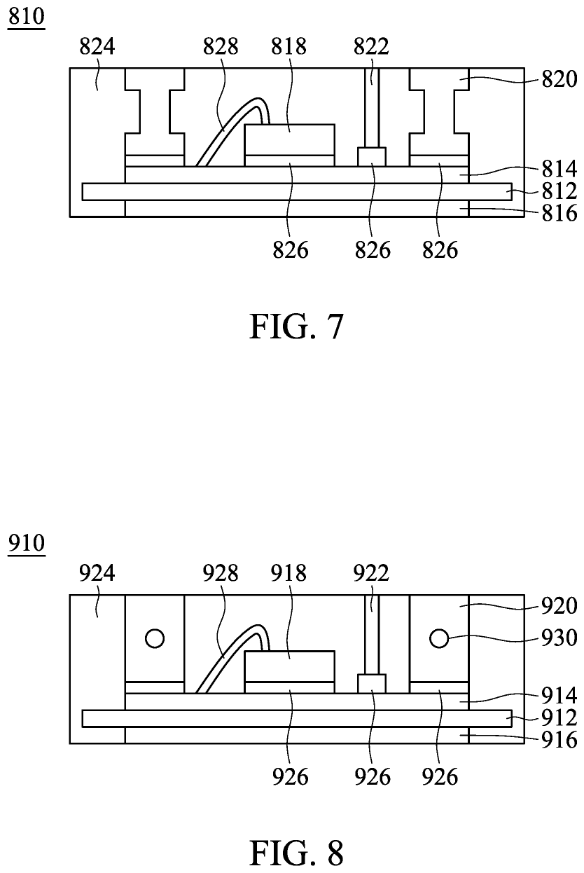

Referring to FIG. 7, in accordance with one embodiment of the present disclosure, a power module structure 810 is provided. FIG. 7 shows a cross-sectional view of the power module structure 810.

As shown in FIG. 7, the power module structure 810 includes a substrate 812, a first copper layer 814, a second copper layer 816, a chip 818, a first metal structure 820, a second metal structure 822, a packaging material 824, solder 826, and a metal wire 828. The configuration and material of each component, the dimensional relationship between the components, and the bonding manner between the components in the power module structure 810 shown in FIG. 7 are similar to those of the power module structure 10 shown in FIG. 1, and will not be described again here. The main difference between the embodiment shown in FIG. 7 and the embodiment shown in FIG. 1 is that the shapes (i.e. three-dimensional structures) of the first metal structures in the power module structure are different. For example, in FIG. 1, the first metal structure 20 is rectangular. In FIG. 7, the first metal structure 820 is irregular in shape, for example, I-shaped, but the present disclosure is not limited thereto, and other suitable shapes (i.e. three-dimensional structures) of the first metal structures are also applicable to the present disclosure. In some embodiments, when the first metal structure 820 is I-shaped, the bonding area and bonding force between the first metal structure 820 and the packaging material 824 can thus be increased.

Referring to FIG. 8, in accordance with one embodiment of the present disclosure, a power module structure 910 is provided. FIG. 8 shows a cross-sectional view of the power module structure 910.

As shown in FIG. 8, the power module structure 910 includes a substrate 912, a first copper layer 914, a second copper layer 916, a chip 918, a first metal structure 920, a second metal structure 922, a packaging material 924, solder 926, and a metal wire 928. The configuration and material of each component, the dimensional relationship between the components, and the bonding manner between the components in the power module structure 910 shown in FIG. 8 are similar to those of the power module structure 10 shown in FIG. 1, and will not be described again here. The main difference between the embodiment shown in FIG. 8 and the embodiment shown in FIG. 1 is that the detailed structures of the first metal structures in the power module structure are different. In FIG. 8, the first metal structure 920 further includes a through hole 930. In some embodiments, when the first metal structure 920 includes the through hole 930, the bonding force between the first metal structure 920 and the packaging material 924 can be increased.

In the power module structure of the present disclosure, the first metal structure and the second metal structure for signal conduction are disposed on the substrate and exposed from the upper surface of the packaging material to conduct signals from the substrate to the surface of the packaging material. Then, the first metal structure and the second metal structure are connected to a power pin and a signal pin respectively through the post-processes. In the present disclosure, the circuit can be shortened to a minimum by conducting signals vertically to achieve rapid conduction of current and signals. Since the first metal structure is a solid structure, large current transmission can be achieved. In addition, the relative positional relationship between the first metal structure, the second metal structure and the packaging material in the disclosed power module structure can be appropriately adjusted according to product requirements, and the manufacturing process is simple. Furthermore, the dimension, quantity, position, shape, three-dimensional structure, etc. of the plurality of first metal structures in the disclosed power module structure can also be adjusted appropriately according to product requirements, and the manufacturing process is simple. For example, designing the first metal structure into an I-shape can increase the bonding area and bonding force between the first metal structure and the packaging material. For another example, designing the first metal structure to include a through-hole structure can increase the bonding force between the first metal structure and the packaging material.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. A power module structure, comprising:
a substrate;
a chip disposed on the substrate;
a first metal structure disposed on the substrate;
a second metal structure disposed on the substrate, wherein, from a cross-sectional view, the first metal structure has a larger width than that of the second metal structure; and
a packaging material covering the substrate and the chip, wherein portions of the first metal structure and the second metal structure are exposed from an upper surface of the packaging material.

2. The power module structure as claimed in claim 1, wherein the substrate comprises aluminum oxide.

3. The power module structure as claimed in claim 1, wherein the chip comprises a power component.

4. The power module structure as claimed in claim 1, wherein the first metal structure and the second metal structure comprise copper, silver or aluminum.

5. The power module structure as claimed in claim 1, wherein upper surfaces of the first metal structure and the second metal structure are on the same plane as the upper surface of the packaging material.

6. The power module structure as claimed in claim 1, wherein upper surfaces of the first metal structure and the second metal structure are higher than the upper surface of the packaging material.

7. The power module structure as claimed in claim 1, wherein upper surfaces of the first metal structure and the second metal structure are lower than the upper surface of the packaging material.

8. The power module structure as claimed in claim 1, further comprising another first metal structure disposed on the substrate, wherein a portion of the other first metal structure is exposed from the upper surface of the packaging material.

9. The power module structure as claimed in claim 8, wherein, from a top view, the first metal structure and the other first metal structure have different areas.

10. The power module structure as claimed in claim 8, wherein, from a top view, the first metal structure and the other first metal structure have different shapes.

11. The power module structure as claimed in claim 10, wherein, from a top view, the first metal structure and the other first metal structure comprise a rectangle, a triangle or a circle in shape.

12. The power module structure as claimed in claim 1, wherein, from a cross-sectional view, the first metal structure comprises a rectangle or an irregular shape.

13. The power module structure as claimed in claim 1, wherein the first metal structure further comprises a through hole.
